(19) United States
(12) Patent Application Publication
(10) Pub. No.: US 2026/0009838 A1
(43) Pub. Date: Jan. 8, 2026

(54) METHOD AND APPARATUS FOR PREDICTING RELIABILITY OF SEMICONDUCTOR DEVICE USING PRE-TRAINED ARTIFICIAL INTELLIGENCE MODEL

(71) Applicant: HEX A.I. Labs Inc., Hwaseong-si (KR)

(72) Inventor: Jin Woo KIM, Hwaseong-si (KR)

(21) Appl. No.: 19/026,993

(22) Filed: Jan. 17, 2025

(30) Foreign Application Priority Data
Jul. 8, 2024 (KR) 10-2024-0089518
Aug. 28, 2024 (KR) 10-2024-0116211

(51) Int. Cl. G01R 31/26

(52) U.S. Cl. CPC G01R 31/2642

(57) ABSTRACT

Embodiments relate to a method for predicting reliability of a semiconductor device using a pre-trained artificial intelligence model, the method comprising: acquiring feature data related to at least one electrical characteristic value extracted based on an application of voltage to the semiconductor device; and determining a reliability evaluation index for the semiconductor device by inputting the feature data into the pre-trained artificial intelligence model.

### CROSS-REFERENCE TO RELATED APPLICATION

This application claims priority to Korean Patent Application No. 10-2024-0089518, filed on Jul. 8, 2024, and Korean Patent Application No. 10-2024-0116211, filed on Aug. 28, 2024, in the Korean Intellectual Property Office, the entirety of which is incorporated herein by reference for all purposes.

### BACKGROUND OF THE INVENTION

### Field of the Invention

The present invention relates to a method and apparatus for predicting reliability of a semiconductor device using a pre-trained artificial intelligence model.

### Description of the Related Art

Semiconductor reliability evaluation is an essential test that determines the quality in the semiconductor manufacturing process. As semiconductor processes become more advanced, manufacturing costs increase, and the importance of ensuring reliability grows, interest in semiconductor reliability evaluation has been increasing.

Conventional semiconductor reliability evaluation is conducted by engineers through destructive testing or physical evaluation, requiring a significant amount of time. Defects in the semiconductor development and mass production process are identified through physical evaluation of randomly extracted samples after mass production has been completed.

However, due to the advancement of semiconductor processes, the manufacturing cost has increased approximately 2.7 times, from $9,800 per wafer in 2018 to $25,000 per wafer in 2022. Given the nature of the semiconductor manufacturing process, which requires a long manufacturing period (approximately 130 days), if the reliability evaluation is not passed, serious economic issues may arise.

In addition, even if reliability is confirmed through physical evaluation of randomly extracted samples, it cannot guarantee the reliability of all mass-produced semiconductor devices. Further, there are limitations to reliability evaluation in that it is engineer-dependent.

Accordingly, there is a need to develop a technology that can perform highly accurate semiconductor reliability evaluation using semiconductor process information, which is necessarily recorded during the semiconductor manufacturing process, without physical evaluation or destructive testing.

### SUMMARY OF THE INVENTION

The present invention is directed to predicting the reliability of semiconductor devices using an artificial intelligence model, based on the electrical characteristics recorded during the manufacturing process of semiconductor devices, without performing physical evaluation or destructive testing.

However, the objectives of the present disclosure are not limited to those mentioned above, and other objectives not mentioned may be clearly understood by a person having ordinary skill in the art to which the present disclosure pertains from the description below.

In accordance with one aspect of the present disclosure, there is provided a method for predicting reliability of a semiconductor device using a pre-trained artificial intelligence model, the method comprising: acquiring feature data related to at least one electrical characteristic value extracted based on an application of voltage to the semiconductor device; and determining a reliability evaluation index for the semiconductor device by inputting the feature data into the pre-trained artificial intelligence model.

Preferably, the acquiring the feature data includes: extracting the at least one electrical characteristic value based on, through an application of voltage to a gate, an application of voltage to a drain, an application of voltage to a source, and an application of voltage to a body, operating region of the semiconductor device.

Preferably, the at least one electrical characteristic value includes at least one of values related to a first gate current, a first drain current, and a first threshold voltage extracted when the semiconductor device operates in a first region corresponding to a linear region, a second drain current and a second body current extracted when the semiconductor device operates in a second region corresponding to a cut-off region, and a third gate current, a third drain current, a third threshold voltage, and a third gate capacitance extracted when the semiconductor device operates in a third region corresponding to a saturation region.

Preferably, the acquiring the feature data further includes: acquiring data related to structural characteristic values of the semiconductor device, process node values, and stress conditions; and acquiring the feature data through preprocessing of the extracted at least one electrical characteristic value, the stress conditions, the structural characteristic values of the semiconductor device, and the process node values.

Preferably, the determining the reliability evaluation index of the semiconductor device includes: determining at least one of hot carrier injection (HCI), bias temperature instability (BTI), time dependent dielectric breakdown (TDDB), or oxide breakdown voltage (Vᵣₐₘₚ) using the pre-trained artificial intelligence model.

Preferably, the determining the reliability evaluation index of the semiconductor device includes: determining at least one of the HCI or the BTI by inputting feature data related to at least four electrical characteristic values into the pre-trained artificial intelligence model, and wherein the at least four electrical characteristic values include four values of a first drain current, a second body current, a second drain current, a third gate current, or a third drain current.

Preferably, the determining the reliability evaluation index of the semiconductor device includes: determining the Vᵣₐₘₚ by inputting feature data related to at least three electrical characteristic values into the pre-trained artificial intelligence model, and wherein the at least three electrical characteristic values include a first gate current, a second drain current, and a third gate capacitance.

Preferably, the determining the reliability evaluation index of the semiconductor device includes: determining the TDDB by inputting feature data related to at least three electrical characteristic values into the pre-trained artificial intelligence model, and wherein the at least three electrical characteristic values include a first gate current, a second drain current, and a third gate current.

Preferably, the method further comprises: predicting reliability lifespan of the semiconductor device by inputting the reliability evaluation index into a lifespan prediction model, and displaying through a display unit at least one of the reliability evaluation index and the reliability lifespan of the semiconductor device to a user.

Preferably, the artificial intelligence model is pre-trained by updating parameters or hyperparameters such that a coefficient of determination, determined based on computation between the determined reliability evaluation index and measured reliability evaluation index, satisfies a pre-set value.

In accordance with another aspect of the present disclosure, an apparatus for predicting reliability of a semiconductor device using a pre-trained artificial intelligence model, the apparatus comprising: a memory storing a reliability prediction program; and a processor configured to load the reliability prediction program from the memory and execute the reliability prediction program, wherein the processor acquires feature data related to at least one electrical characteristic value extracted based on an application of voltage to the semiconductor device and determines a reliability evaluation index for the semiconductor device by inputting the feature data into the pre-trained artificial intelligence model.

Preferably, the processor includes: extracting the at least one electrical characteristic value based on an application of voltage to a gate, an application of voltage to a drain, an application of voltage to a source, and an application of voltage to a body, in consideration of an operating region of the semiconductor device.

Preferably, the at least one electrical characteristic value includes at least one of values related to a first gate current, a first drain current, and a first threshold voltage extracted when the semiconductor device operates in a first region corresponding to a linear region, a second drain current and a second body current extracted when the semiconductor device operates in a second region corresponding to a cut-off region, and a third gate current, a third drain current, a third threshold voltage, and a third gate capacitance extracted when the semiconductor device operates in a third region corresponding to a saturation region.

Preferably, the processor acquires data related to structural characteristic values of the semiconductor device, process node values, and stress conditions, and acquires the feature data through preprocessing of the extracted at least one electrical characteristic value, the stress conditions, the structural characteristic values of the semiconductor device, and the process node values.

Preferably, the processor determines at least one of hot carrier injection (HCI), bias temperature instability (BTI), time dependent dielectric breakdown (TDDB), or oxide breakdown voltage (Vᵣₐₘₚ) using the pre-trained artificial intelligence model.

Preferably, the processor determines at least one of the HCI or the BTI by inputting feature data related to at least four electrical characteristic values into the pre-trained artificial intelligence model, and wherein the at least four electrical characteristic values include four values of a first drain current, a second body current, a second drain current, a third gate current, or a third drain current.

Preferably, the processor determines the Vᵣₐₘₚ by inputting feature data related to at least three electrical characteristic values into the pre-trained artificial intelligence model, and wherein the at least three electrical characteristic values include a first gate current, a second drain current, and a third gate capacitance.

Preferably, the processor determines the TDDB by inputting feature data related to at least three electrical characteristic values into the pre-trained artificial intelligence model, and wherein the at least three electrical characteristic values include a first gate current, a second drain current, and a third gate current.

Preferably, the processor predicts reliability lifespan of the semiconductor device by inputting the reliability evaluation index into a lifespan prediction model.

In accordance with a still another aspect of the present disclosure, there is provided a non-transitory computer-readable recording medium storing a computer program, the computer program, when executed by a processor, comprising instructions for causing the processor to perform a method for predicting reliability of a semiconductor device using a pre-trained artificial intelligence model, the method comprising: acquiring feature data related to at least one electrical characteristic value extracted based on an application of voltage to the semiconductor device; and determining a reliability evaluation index for the semiconductor device by inputting the feature data into the pre-trained artificial intelligence model.

According to an embodiment of the present invention, by inputting feature data related to electrical characteristic values, which are necessarily recorded during the semiconductor manufacturing process, into a pre-trained artificial intelligence model to determine a reliability evaluation index for the semiconductor device, it is possible to dramatically reduce the reliability evaluation time without the need for testing facilities or equipment, personnel for reliability evaluation, or wafer consumption.

In addition, according to an embodiment of the present invention, by reducing the reliability evaluation time, it is possible to significantly shorten the semiconductor development and mass production periods.

### BRIEF DESCRIPTION OF THE DRAWINGS

FIG. 1 is a block diagram illustrating an apparatus for predicting reliability according to an embodiment of the present invention.

FIG. 2 is a block diagram conceptually illustrating the functions of a reliability prediction program according to an embodiment of the present invention.

FIG. 3 is a flowchart illustrating a method for predicting reliability according to an embodiment of the present invention.

FIGS. 4, 5A, 5B, 6A and 6B are views exemplarily illustrating the accuracy of predicted HCI, Vᵣₐₘₚ, and TDDB depending on the types and number of electrical characteristic values according to an embodiment of the present invention.

### DETAILED DESCRIPTION OF THE INVENTION

The advantages and features of embodiments and methods of accomplishing these will be clearly understood from the following description taken in conjunction with the accompanying drawings. However, embodiments are not limited to those embodiments described, as embodiments may be implemented in various forms. It should be noted that the present embodiments are provided to make a full disclosure and also to allow those skilled in the art to know the full range of the embodiments. Therefore, the embodiments are to be defined only by the scope of the appended claims.

In describing the embodiments of the present disclosure, if it is determined that detailed description of related known components or functions unnecessarily obscures the gist of the present disclosure, the detailed description thereof will be omitted. Further, the terminologies to be described below are defined in consideration of functions of the embodiments of the present disclosure and may vary depending on a user's or an operator's intention or practice. Accordingly, the definition thereof may be made on a basis of the content throughout the specification.

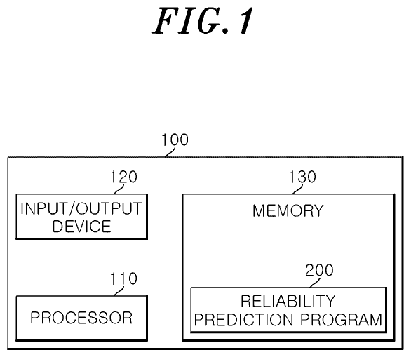

FIG. 1 is a block diagram illustrating an apparatus for predicting reliability according to an embodiment of the present invention.

With reference to FIG. 1, an apparatus 100 for predicting reliability may include a processor 110, an input/output device 120, and a memory 130.

The processor 110 may generally control the operation of the apparatus 100 for predicting reliability.

The processor 110 may receive feature data related to at least one electrical characteristic value extracted based on voltage application to a semiconductor device using the input/output device 120.

In the present invention, although it has been described that the feature data related to at least one electrical characteristic value extracted based on voltage application to the semiconductor device is input through the input/output device 120, the present invention is not limited thereto. That is, depending on the embodiment, the apparatus 100 for predicting reliability may include a transceiver (not illustrated), and the apparatus 100 for predicting reliability may receive feature data related to at least one electrical characteristic value extracted based on voltage application to the semiconductor device using the transceiver. Additionally, the feature data related to at least one electrical characteristic value extracted based on voltage application to the semiconductor device may also be generated within the apparatus 100 for predicting reliability.

The processor 110 may receive feature data related to at least one electrical characteristic value extracted based on voltage application to the semiconductor device, and using a pre-trained artificial intelligence model, determine a reliability evaluation index for the semiconductor device.

The input/output device 120 may include one or more input devices and/or one or more output devices. For example, the input devices may include a microphone, keyboard, mouse, touch screen, and the like, and the output devices may include a display, speaker, and the like.

The memory 130 may store a reliability prediction program 200 and information necessary for the execution of the reliability prediction program 200.

In the present specification, the reliability prediction program 200 may refer to software that includes instructions for receiving feature data related to at least one electrical characteristic value extracted based on voltage application to the semiconductor device, and using a pre-trained artificial intelligence model to determine the reliability evaluation index for the semiconductor device.

In addition, in the present specification, the reliability prediction program 200 may refer to software that includes instructions for receiving the reliability evaluation index for the semiconductor device, and using a lifespan prediction model to predict the reliability lifespan of the semiconductor device.

The processor 110 may load the reliability prediction program 200 and the information necessary for the execution of the reliability prediction program 200 from the memory 130 in order to execute the reliability prediction program 200.

The processor 110 may execute the reliability prediction program 200, receive feature data related to the electrical characteristic value of the semiconductor device, determine the reliability evaluation index for the semiconductor device, and input the reliability evaluation index into a lifespan prediction model to predict the reliability lifespan of the semiconductor device.

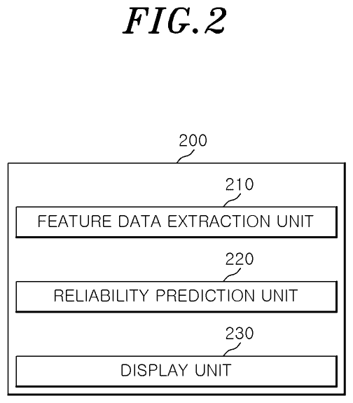

The functions and/or operations of the reliability prediction program 200 will be described in detail with reference to FIG. 2.

FIG. 2 is a block diagram conceptually illustrating the functions of a reliability prediction program according to an embodiment of the present invention.

With reference to FIG. 2, the reliability prediction program 200 may include a feature data extraction unit 210, a reliability prediction unit 220 and a display unit 230.

The feature data extraction unit 210, the reliability prediction unit 220 and the display unit 230 illustrated in FIG. 2 are conceptually divided to describe the functions of the reliability prediction program 200 in a simplified manner and the present invention is not limited thereto. According to embodiments, the functions of the feature data extraction unit 210, the reliability prediction unit 220 and the display unit 230 may be merged or separated, and they may be implemented as a series of instructions included in a single program.

First, the feature data extraction unit 210 may acquire feature data related to at least one electrical characteristic value extracted based on voltage application to the semiconductor device.

Here, the semiconductor device may refer to any semiconductor transistor consisting of a source, drain, gate, and body (or substrate), and the semiconductor device may have structures such as planar, fin, or gate-all-around. Additionally, the electrical characteristic value may refer to a value representing the electrical result recorded during the manufacturing process of the semiconductor device.

Specifically, the feature data extraction unit 210 may extract at least one electrical characteristic value, taking into account the measurement conditions for the semiconductor device (e.g., voltage application conditions or the operating region conditions of the device).

For example, the feature data extraction unit 210 may extract at least one electrical characteristic value based on the voltage application to the gate, drain, source, and body (or substrate), considering the operating region of the semiconductor device.

More specifically, the electrical characteristic value for the semiconductor device may include values related to a first gate current, a first drain current, and a first threshold voltage extracted when the semiconductor device operates in a first region corresponding to a linear region.

Additionally, the electrical characteristic value may include values related to a second drain current and a second body current extracted when the semiconductor device operates in a second region corresponding to a cut-off region.

Additionally, the electrical characteristic value may include values related to a third gate current, a third drain current, a third threshold voltage, and a third gate capacitance extracted when the semiconductor device operates in a third region corresponding to a saturation region.

Meanwhile, the feature data extraction unit 210 may further acquire data related to the structural characteristic values of the semiconductor device, process node values, and stress conditions.

Here, the structural characteristic values of the semiconductor device may refer to characteristic values that define the structure of the semiconductor device. For example, these may include a width, length, and pitch (e.g., pc pitch) corresponding to the structure of the semiconductor device, such as planar, fin, gate-all-around, or nano-sheet. In addition, the process node values of the semiconductor device may refer to values used to define the size and density of the device during the manufacturing process. For example, it may include values such as 2, 3, 4, 5, 7, 8, 10, 14, 20 nm, and so on. However, the process node values mentioned above are merely examples, and within the scope of achieving the objectives of the present invention, process node values for all processes may be included.

Additionally, the stress conditions may refer to conditions used to evaluate the verification of the electrical characteristics or durability of the device by using a voltage higher than the typical operating conditions. For example, these may include the stress voltage applied to the source, drain, gate, and body (or substrate), stress temperature, and the duration for which the stress is applied.

Additionally, the feature data extraction unit 210 may acquire feature data through preprocessing of at least one electrical characteristic value, stress conditions, structural characteristic values of the semiconductor device, and process node values.

Specifically, the feature data extraction unit 210 may acquire feature data for input into the pre-trained artificial intelligence model through data normalization (e.g., min-max scaling), textual data encoding (e.g., converting textual data such as process node, number of fins, number of pcs, number of nano sheets, etc., into numerical values), and handling of missing or outlier values (e.g., removing missing or outlier values or replacing them with the mean).

Next, the reliability prediction unit 220 may input the feature data into the pre-trained artificial intelligence model to determine the reliability evaluation index for the semiconductor device.

Here, the pre-trained artificial intelligence model may refer to a machine learning or deep learning-based artificial intelligence model that is pre-trained to determine the reliability evaluation index for the semiconductor device. For example, the pre-trained model may refer to an artificial intelligence model based on decision tree algorithms (e.g., random forest, LightGBM, XGBoost) or a deep learning model (e.g., MLP, CNN, etc.).

Meanwhile, the machine learning or deep learning-based artificial intelligence model is merely an example and may be varied within the scope of achieving the objectives of the present invention.

In addition, the reliability evaluation index for the semiconductor device may refer to characteristic values (e.g., threshold voltage, stress voltage, stress current, stress time, etc.) or the rate of change of characteristic values corresponding to the global standard semiconductor reliability evaluation items defined by the Joint Electron Device Engineering Council (JEDEC).

Meanwhile, the reliability evaluation index for the semiconductor device may include reliability evaluation indices corresponding to wafer-level reliability and package-level reliability.

Here, the reliability evaluation index corresponding to wafer-level reliability is classified into back-end-of-line (BEOL) and front-end-of-line (FEOL) processes. The FEOL reliability evaluation index may include hot carrier injection (HCI), bias temperature instability (BTI), time dependent dielectric breakdown (TDDB), and oxide breakdown voltage (Vᵣₐₘₚ). The BEOL reliability evaluation index may include electro migration (EM), stress migration (SM), TDDB, and the like.

Additionally, the reliability evaluation index corresponding to package-level reliability may include high temperature operation lifespan (HTOL).

Meanwhile, the reliability evaluation index for the semiconductor device is merely an example and may be varied within the scope of achieving the objectives of the present invention.

According to an embodiment of the present invention, the reliability prediction unit 220 may determine at least one of HCI, BTI, TDDB, or Vᵣₐₘₚ using a pre-trained artificial intelligence model.

Specifically, the reliability prediction unit 220 may input feature data related to at least four electrical characteristic values into the pre-trained artificial intelligence model to determine at least one of HCI or BTI.

Here, the at least four electrical characteristic values may include four of values related to the first drain current, second body current, second drain current, third gate current, and third drain current.

Additionally, the reliability prediction unit 220 may input feature data related to at least three electrical characteristic values into the pre-trained artificial intelligence model to determine Vᵣₐₘₚ.

Here, the at least three electrical characteristic values may include the first gate current, second drain current, and third gate capacitance.

Additionally, the reliability prediction unit 220 may input feature data related to at least three electrical characteristic values into the pre-trained artificial intelligence model to determine TDDB.

Here, the at least three electrical characteristic values may include the first gate current, second drain current, and third gate current.

Additionally, the reliability prediction unit 220 may input the determined reliability evaluation index into a lifespan prediction model to predict the reliability lifespan of the semiconductor device. Here, the lifespan prediction model may be a model that receives characteristic values corresponding to the reliability evaluation items and calculates the semiconductor reliability lifespan corresponding to the operating voltage. This model may include previously known models.

For example, the reliability prediction unit 220 may input the stress voltage corresponding to the determined reliability evaluation index into the lifespan prediction model to predict the reliability lifespan of the semiconductor device corresponding to the operating voltage.

Meanwhile, according to an embodiment of the present invention, the artificial intelligence model may be trained by updating parameters or hyperparameters such that a coefficient of determination, determined based on the computation between the determined reliability evaluation index and the measured reliability evaluation index, satisfies a pre-set value. Here, the coefficient of determination may refer to the explanatory power of an independent variable with respect to a dependent variable.

For example, a dataset including the measurement conditions, electrical characteristic values, structural characteristic values, process node values, stress conditions, and reliability evaluation index for the semiconductor device may be randomly divided into a training dataset (e.g., 70%), a validation dataset (e.g., 20%), and a test dataset (e.g., 10%).

Here, the artificial intelligence model may be first trained using the training dataset by receiving feature data and outputting the reliability evaluation index, and then be secondarily trained using the validation dataset such that the coefficient of determination satisfies a pre-set value (e.g., 0.87).

Then, when the coefficient of determination, determined based on the computation between the reliability evaluation index determined using the test dataset input into the artificial intelligence model and the measured reliability evaluation index, does not satisfy the pre-set value (e.g., 0.87), the artificial intelligence model may be re-trained using a new training dataset through preprocessing or hyperparameter adjusting.

Next, the display unit 230 may display at least one of the reliability evaluation index and reliability lifespan of the semiconductor device to a user.

Here, the display unit 230 can be a monitor, a screen, or mobile device, etc. The reliability evaluation index and reliability lifespan of the semiconductor device may be provided to the user through display unit 230

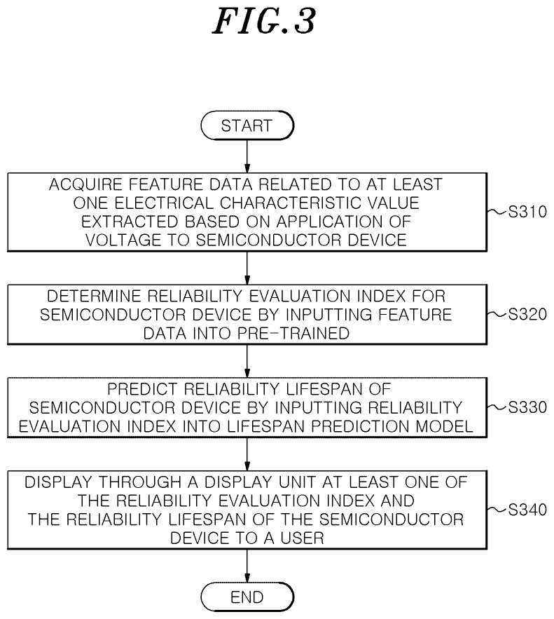

FIG. 3 is a flowchart illustrating a method for predicting reliability according to an embodiment of the present invention.

With reference to FIG. 2 and FIG. 3, the feature data extraction unit 210 may acquire feature data related to at least one electrical characteristic value extracted based on voltage application to the semiconductor device (S310).

Then, the reliability prediction unit 220 may determine the reliability evaluation index for the semiconductor device by inputting the feature data into the pre-trained artificial intelligence model (S320). Here, the artificial intelligence model may be trained to output the reliability evaluation index by receiving feature data, such that the artificial intelligence model satisfies a pre-set coefficient of determination.

Additionally, the reliability prediction unit 220 may predict the reliability lifespan of the semiconductor device by inputting the reliability evaluation index into the lifespan prediction model (S330).

Additionally, the display unit 230 may display at least one of the reliability evaluation index and the reliability lifespan of the semiconductor device to a user (S340).

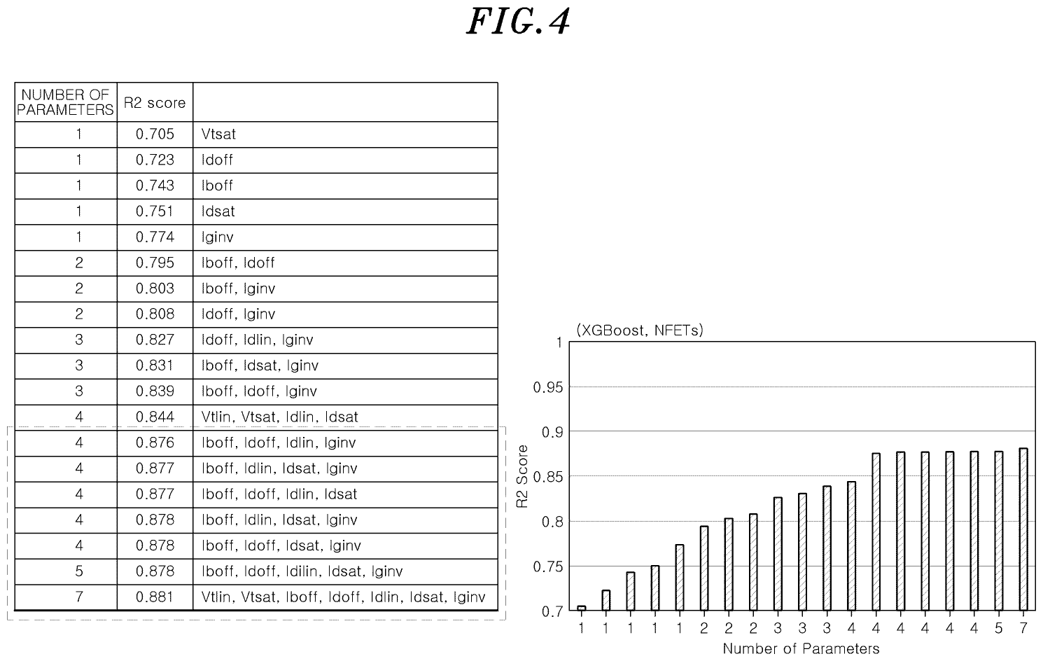

FIG. 4 to FIG. 6 are views exemplarily illustrating the accuracy of predicted HCI, Vᵣₐₘₚ, and TDDB depending on the types and number of electrical characteristic values according to an embodiment of the present invention.

With reference to FIG. 2 and FIG. 4 to FIG. 6, the feature data extraction unit 210 may acquire feature data related to at least one electrical characteristic value extracted based on voltage application to the semiconductor device.

Here, the at least one electrical characteristic value may include at least one of values related to the first gate current (Igo), first drain current (Idlin), and first threshold voltage (Vtlin) extracted when the semiconductor device operates in the first region corresponding to the linear region, the second drain current (Idoff) and second body current (Iboff) extracted when the semiconductor device operates in the second region corresponding to the cut-off region, and the third gate current (Iginv), third drain current (Idsat), third threshold voltage (Vtsat), and third gate capacitance (Cinv) extracted when the semiconductor device operates in the third region corresponding to the saturation region.

Additionally, the reliability prediction unit 220 may input feature data related to at least one electrical characteristic value into the pre-trained artificial intelligence model to determine the reliability evaluation index.

First, FIG. 4 illustrates an experimental example of the coefficient of determination determined based on the computation for the predicted HCI and the measured HCI, depending on the types and number of electrical characteristic values.

With reference to FIG. 4, it can be seen that as the number of electrical characteristic values increases, the coefficient of determination tends to rise. However, the coefficient of determination converges at a certain level or more, and a significant coefficient of determination is derived depending on the type of electrical characteristic value.

Specifically, it can be seen that when feature data including at least four values of the first drain current (Idlin), second body current (Iboff), second drain current (Idoff), third gate current (Iginv), or third drain current (Idsat) is input into the pre-trained artificial intelligence model to determine HCI, a significant result with a coefficient of determination of 0.87 or more can be derived.

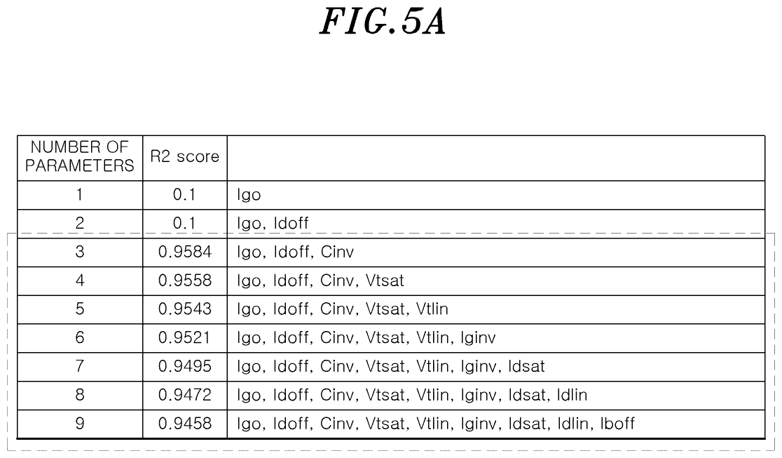

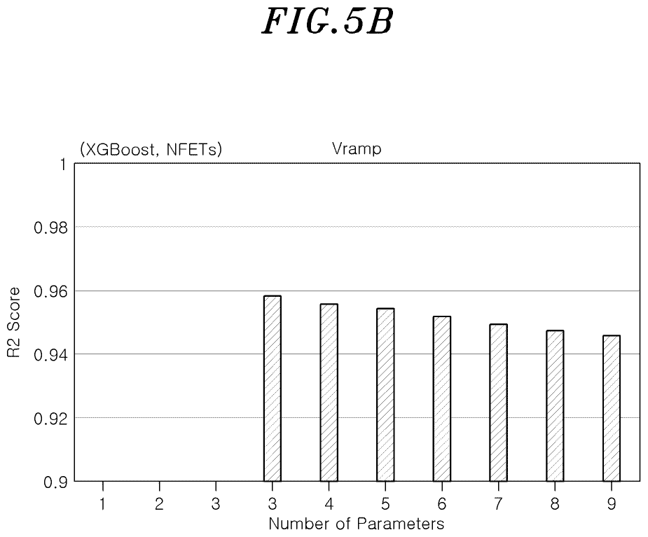

Next, FIG. 5A and FIG. 5B illustrate an experimental example of the coefficient of determination determined based on the computation for the predicted Vᵣₐₘₚ and the measured Vᵣₐₘₚ, depending on the types and number of electrical characteristic values.

With reference to FIG. 5A and FIG. 5B, it can be seen that a significant coefficient of determination is derived depending on the types of electrical characteristic values.

Specifically, it can be seen that when feature data including values related to the first gate current (Igo), second drain current (Idoff), and third gate capacitance (Cinv) is input into the pre-trained artificial intelligence model to determine Vᵣₐₘₚ, a significant result with a coefficient of determination of 0.87 or more can be derived.

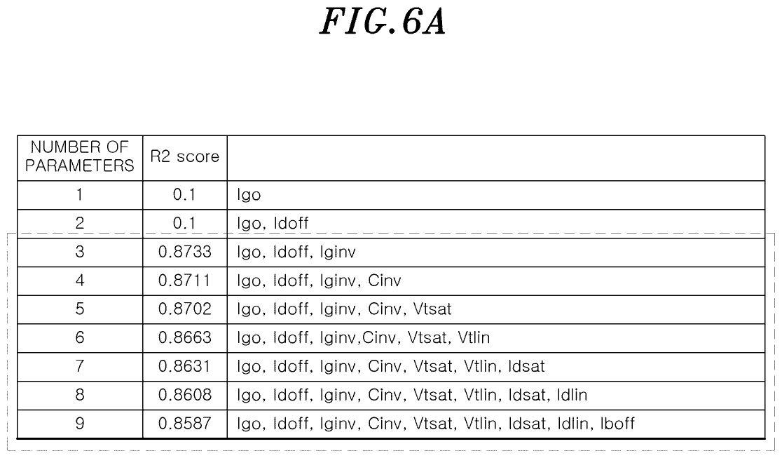

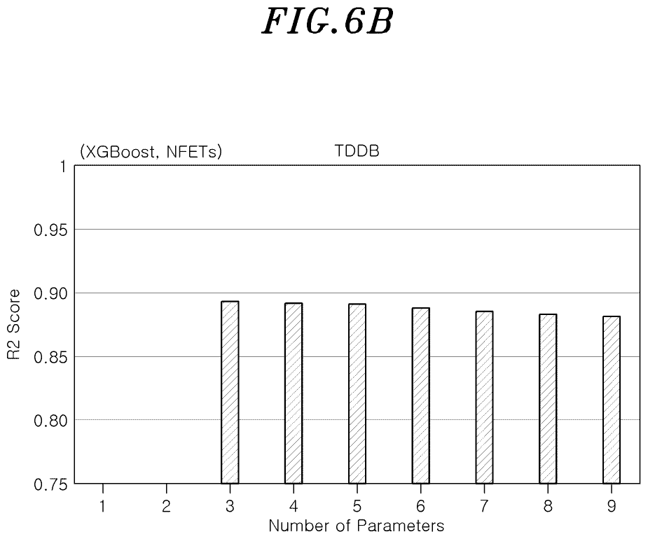

Next, FIG. 6A and FIG. 6B illustrate an experimental example of the coefficient of determination determined based on the computation for the predicted TDDB and the measured TDDB, depending on the types and number of electrical characteristic values.

With reference to FIG. 6A and FIG. 6B, it can be seen that a significant coefficient of determination is derived depending on the types of electrical characteristic values.

Specifically, it can be seen that when feature data including values related to the first gate current (Igo), second drain current (Idoff), and third gate current (Iginv) is input into the pre-trained artificial intelligence model to determine TDDB, a significant result with a coefficient of determination of 0.87 or more can be derived.

Combinations of each block of the block diagrams and each step of the flowchart attached to the present disclosure may be performed by computer program instructions. Since these computer program instructions can be installed in an encoding processor of a general-purpose computer, a special-purpose computer, or other programmable data processing equipment, the instructions executed through the encoding processor of the computer or other programmable data processing equipment generate means for executing functions described in each block of the block diagrams or each step of the flowchart. These computer program instructions may also be stored in a computer-usable or computer-readable memory that can be directed to computers or other programmable data processing equipment to implement functions in a particular way, and thus the instructions stored in the computer-usable or computer-readable memory can also produce manufactured items containing instruction means for executing the functions described in each block of the block diagram or each step of the flowchart. Since the computer program instructions can also be installed in a computer or other programmable data processing equipment, a series of operational steps may be performed on the computer or other programmable data processing equipment to create a process that is executed by the computer, thereby providing steps for executing the functions described in each block of the block diagrams and each step of the flowchart through the instructions.

Additionally, each block or each step may represent a module, a segment, or some code that includes one or more executable instructions for executing specified logical function(s). Additionally, it should be noted that, in some alternative embodiments, the functions mentioned in blocks or steps are executed out of order. For example, two blocks or steps shown in succession may be performed substantially simultaneously, or the blocks or steps may sometimes be performed in reverse order depending on the corresponding function.

The above description is merely exemplary description of the technical scope of the present disclosure, and it will be understood by those skilled in the art that various changes and modifications can be made without departing from original characteristics of the present disclosure. Therefore, the embodiments disclosed in the present disclosure are intended to explain, not to limit, the technical scope of the present disclosure, and the technical scope of the present disclosure is not limited by the embodiments. The protection scope of the present disclosure should be interpreted based on the following claims and it should be appreciated that all technical scopes included within a range equivalent thereto are included in the protection scope of the present disclosure.

What is claimed is:

1. A method for predicting reliability of a semiconductor device using a pre-trained artificial intelligence model, the method comprising:
acquiring feature data related to at least one electrical characteristic value extracted based on an application of voltage to the semiconductor device; and
determining a reliability evaluation index for the semiconductor device by inputting the feature data into the pre-trained artificial intelligence model.

2. The method of claim 1, wherein the acquiring the feature data includes:
extracting the at least one electrical characteristic value based on, through an application of voltage to a gate, an application of voltage to a drain, an application of voltage to a source, and an application of voltage to a body, an operating region of the semiconductor device.

3. The method of claim 1, wherein the at least one electrical characteristic value includes at least one of values related to a first gate current, a first drain current, and a first threshold voltage extracted when the semiconductor device operates in a first region corresponding to a linear region, a second drain current and a second body current extracted when the semiconductor device operates in a second region corresponding to a cut-off region, and a third gate current, a third drain current, a third threshold voltage, and a third gate capacitance extracted when the semiconductor device operates in a third region corresponding to a saturation region.

4. The method of claim 1, wherein the acquiring the feature data includes:
acquiring data related to structural characteristic values of the semiconductor device, process node values, and stress conditions; and
acquiring the feature data through preprocessing of the extracted at least one electrical characteristic value, the stress conditions, the structural characteristic values of the semiconductor device, and the process node values.

5. The method of claim 1, wherein the determining the reliability evaluation index of the semiconductor device includes:
determining at least one of hot carrier injection (HCI), bias temperature instability (BTI), time dependent dielectric breakdown (TDDB), or oxide breakdown voltage (Vᵣₐₘₚ) using the pre-trained artificial intelligence model.

6. The method of claim 5, wherein the determining the reliability evaluation index of the semiconductor device further includes:
determining at least one of the HCI or the BTI by inputting feature data related to at least four electrical characteristic values into the pre-trained artificial intelligence model, and
wherein the at least four electrical characteristic values include four values of a first drain current, a second body current, a second drain current, a third gate current, or a third drain current.

7. The method of claim 5, wherein the determining the reliability evaluation index of the semiconductor device further includes:
determining the Vᵣₐₘₚ by inputting feature data related to at least three electrical characteristic values into the pre-trained artificial intelligence model, and
wherein the at least three electrical characteristic values include a first gate current, a second drain current, and a third gate capacitance.

8. The method of claim 5, wherein the determining the reliability evaluation index of the semiconductor device further includes:
determining the TDDB by inputting feature data related to at least three electrical characteristic values into the pre-trained artificial intelligence model, and
wherein the at least three electrical characteristic values include a first gate current, a second drain current, and a third gate current.

9. The method of claim 1, further comprising:
predicting reliability lifespan of the semiconductor device by inputting the reliability evaluation index into a lifespan prediction model, and
displaying through a display unit at least one of the reliability evaluation index and the reliability lifespan of the semiconductor device to a user.

10. The method of claim 1, wherein the artificial intelligence model is pre-trained by updating parameters or hyperparameters such that a coefficient of determination, determined based on computation between the determined reliability evaluation index and measured reliability evaluation index, satisfies a pre-set value.

11. An apparatus for predicting reliability of a semiconductor device using a pre-trained artificial intelligence model, the apparatus comprising:
a memory storing a reliability prediction program; and
a processor configured to load the reliability prediction program from the memory and execute the reliability prediction program,
wherein the processor acquires feature data related to at least one electrical characteristic value extracted based on an application of voltage to the semiconductor device and determines a reliability evaluation index for the semiconductor device by inputting the feature data into the pre-trained artificial intelligence model.

12. The apparatus of claim 11, wherein the processor includes:
extracting the at least one electrical characteristic value based on, through an application of voltage to a gate, an application of voltage to a drain, an application of voltage to a source, and an application of voltage to a body, an operating region of the semiconductor device.

13. The apparatus of claim 11, wherein the at least one electrical characteristic value includes at least one of values related to a first gate current, a first drain current, and a first threshold voltage extracted when the semiconductor device operates in a first region corresponding to a linear region, a second drain current and a second body current extracted when the semiconductor device operates in a second region corresponding to a cut-off region, and a third gate current, a third drain current, a third threshold voltage, and a third gate capacitance extracted when the semiconductor device operates in a third region corresponding to a saturation region.

14. The apparatus of claim 11, wherein the processor acquires data related to structural characteristic values of the semiconductor device, process node values, and stress conditions, and acquires the feature data through preprocessing of the extracted at least one electrical characteristic value, the stress conditions, the structural characteristic values of the semiconductor device, and the process node values.

15. The apparatus of claim 11, wherein the processor determines at least one of hot carrier injection (HCI), bias temperature instability (BTI), time dependent dielectric breakdown (TDDB), or oxide breakdown voltage (Vᵣₐₘₚ) using the pre-trained artificial intelligence model.

16. The apparatus of claim 15, wherein the processor determines at least one of the HCI or the BTI by inputting feature data related to at least four electrical characteristic values into the pre-trained artificial intelligence model, and
wherein the at least four electrical characteristic values include four values of a first drain current, a second body current, a second drain current, a third gate current, or a third drain current.

17. The apparatus of claim 15, wherein the processor determines the Vᵣₐₘₚ by inputting feature data related to at least three electrical characteristic values into the pre-trained artificial intelligence model, and
wherein the at least three electrical characteristic values include a first gate current, a second drain current, and a third gate capacitance.

18. The apparatus of claim 15, wherein the processor determines the TDDB by inputting feature data related to at least three electrical characteristic values into the pre-trained artificial intelligence model, and
wherein the at least three electrical characteristic values include a first gate current, a second drain current, and a third gate current.

19. The apparatus of claim 11, wherein the processor predicts reliability lifespan of the semiconductor device by inputting the reliability evaluation index into a lifespan prediction model and displays through a display unit at least one of the reliability evaluation index and the reliability lifespan of the semiconductor device to a user.

20. A non-transitory computer-readable recording medium storing a computer program, the computer program, when executed by a processor, comprising instructions for causing the processor to perform a method for predicting reliability of a semiconductor device using a pre-trained artificial intelligence model, the method comprising:
acquiring feature data related to at least one electrical characteristic value extracted based on an application of voltage to the semiconductor device; and
determining a reliability evaluation index for the semiconductor device by inputting the feature data into the pre-trained artificial intelligence model.
